(19) United States
(12) Patent Application Publication
(10) Pub. No.: US 2012/0222885 A1
(43) Pub. Date: Sep. 6, 2012

(54) Transparent conductive film for optoelectronic device

(75) Inventors: Wingkeung MAK, Hong Kong (CN); Hotong LEE, Hong Kong (CN)

(73) Assignee: SAE Magnetics (H.K.) Ltd., Hong Kong (CN)

(21) Appl. No.: 13/064,727

(22) Filed: Apr. 11, 2011

(30) Foreign Application Priority Data
Mar. 1, 2011 (CN) 201110048205.3

(51) Int. Cl. H01B 5/00; B82Y 30/00

(52) U.S. Cl. 174/126.1; 977/762; 977/773

(57) ABSTRACT

A transparent conductive (TC) film includes a main transparent conductive layer and a plurality of conductors electrically contacting with the main transparent conductive layer. The conductors are disposed on the surface of the main transparent conductive layer separately from each other. The transparent conductive film of the present invention has numerous separate conductors to collect electrical current which flow in the TC film, thereby reducing the internal resistance of the TC film while keeping the light transmission unchanged. Furthermore, the new conductor layout reduces the risk of the TC film from high current density damages, thereby achieving better reliability.

This application claims the benefit of Chinese Patent Application No. 201110048205.3, filed on Mar. 1, 2011, the entire content of which is hereby incorporated by reference in this application.

### FIELD OF THE INVENTION

The present invention relates to a transparent conductive (TC) film with conductors disposed thereon for optoelectronic (OE) device.

### BACKGROUND OF THE INVENTION

Transparent conductive (TC) film is widely used in optoelectronic (OE) products including light emitting device and/or light receiving device, such as liquid crystal display (LCD), touch panel, photovoltaic (PV) cell and organic or inorganic electroluminescence (EL) device.

In general, TC film can be classified into three types. One type is homogenous TC film, which can be made of any material in single-layer or multi-layer thin-film form, as long as the material is substantially transparent to light and has electrical conducting properties. In the light of high optical transparency, metal oxides (such as indium tin oxide (ITO), antinomy tin oxide (ATO), zinc oxide (ZnO) and their derivative), graphene and the organic materials (such as PEDOT) are commonly used to form TC film.

Another type of TC film has composite structure, which includes a main body and some high conductivity constituents, such as sub-micron size particle, nano-wire, nano-tube and plasmonic device, embedded in the main body to form a substantially conducting and transparent layer.

An ideal TC film should have high optical transmission and low electrical resistivity to conserve energy, deliver power and resource utilization. For the same type of TC film, once the thickness of the film decreases, both of the sheet resistance and transmission of the film increase. On the other hand, the thicker the film used, the sheet resistance and transmission of the film will be reduced. This is commonly known as the natural trade-off between transparency and conductivity of TC material. With this constraint, the practical parameters of TC film in each OE applications, such as choice of material and film thickness, are the result of compromization (or optimization) TC material trade-off.

To improve the energy efficiency, another type of TC film is produced. This type of TC film has hybrid structure, which is formed by adding an additional conducting layer (made of good conductors) on surface of a primary TC layer. The conducting layer has a layout in the form of bus-bar, fish-bone or network to assist current collection. FIG. 1 shows a hybrid structure TC film 110 with a bus-bar structure 111 used on OE device 120. As shown in FIG. 1, the OE device 120 includes a substrate layer 121, an active layer 122 and an intermediate layer 123 which is sandwiched between the substrate layer 121 and the active layer 122. The active layer 122 is used for light emission or light absorption, while the TC film 110 which overlays the active layer 122 is used for light transmission and electrical conduction. The bus-bar conductor 111 of the TC film 110 serve as a low resistance path for efficient current transportation, thus, the bus-bar structure 111 can effectively reduce the sheet resistance (or device internal resistance) of the TC film 110.

To maximize the benefit of current collector (conductor 111 on TC film 110), for instance in photovoltaic industry, often keep the width of the current conductor as long as that is reliable and can be manufactured. FIG. 2 shows the bus-bar structure 111 found on most crystalline silicon solar cell. The current collector (bus-bar structure 111) can be made by aluminum, nickel or conducting paste containing silver particle and so on, which has higher conductivity compared with that of the primary TC layer 112. Thus, the electrical current tends to direct toward the collector when flowing in the TC film 110. In other words, the current collector 111 may carry large amount of current, which flow though uniformly in primary TC layer 112 originally. Generally, such a high current density in the bus-bar collector 111 may cause some adverse phenomena, such as electromigration and joule-heating. Furthermore, because of the long conductor structure on the TC film 110 surface, another unreliable performance is produced, that is the fast catastrophic damage such as melting of inorganic thin-film PV and slow degradation caused by crystallization of organic molecule in OLED material. It can be seen in FIG. 3, which shows the plot of heat density for the TC film 110, the current is building up along the collector 111 and the hottest region is located near the joint of the bus 111a and the bar 111b. The long collector structure (the bus 111a) further suffers from other imperfection during manufacturing, such as the discontinuity due to defect or cracking 130 as shown in FIG. 3. By this token, the tremendous heat density generated around the discontinuous will damage the thin-film device easily and carry the most serious reliability concern.

Hence, it is desired to provide a transparent conductive (TC) film with high light transmission, low internal resistance and good reliability.

### SUMMARY OF THE INVENTION

One objective of the present invention is to provide a transparent conductive (TC) film with a plurality of separate conductors disposed on the surface thereof to reduce internal resistance and/or allow thinner TC film to be used with no impairment in device efficiency, thereby improving the performance and energy efficiency of the optoelectronic device.

To achieve above objectives, the present invention provides a transparent conductive (TC) film including a main transparent conductive layer and a plurality of conductors electrically contacting with the main transparent conductive layer. The conductors are disposed on the surface of the main transparent conductive layer separately from each other for collecting electrical current which flow in the vicinity, thereby reducing the internal resistance and/or allowing thinner TC film to be used with no impairment in application performance.

Preferably, the conductors extend along the direction of the electrical current which flows in the transparent conductive film.

In a preferred embodiment, the conductors are arranged in rows. Preferably, the conductors located on two adjacent rows are staggered with each other.

In another preferred embodiment, the conductors are arranged to be a round shape formed by a series of concentric circles. Preferably, the conductors located on two adjacent concentric circles are staggered with each other.

Preferably, the conductor is a conducting thin film whose surface contacts with the main transparent conductive layer fully.

Preferably, the shape of the conductor is straight strip, Y-branch shape or H-shape.

Preferably, the conductor is a wire which has at least two electric contacts to electrically contact with the main transparent conductive layer.

Preferably, the conductor is made of the same material as that of the main transparent conductive layer.

Preferably, the main transparent conductive layer has a layer body which incorporates nano-particle, nano-wire or plasmonic structure or layers therein.

Preferably, the main transparent conductive layer contacts with active layer of the optoelectronic device directly.

In comparison with the prior art, because of the transparent conductive film of the present invention having numerous separate conductors formed thereon to serve as low resistive paths for collecting electrical current which flow in the TC film, thus, the present invention can increase the energy efficiency and improve the performance of OE device by two ways: one way is increasing the light transmission by using thinner main transparent conductive layer while keeping the internal resistance (electrical loss) at the same level with the help of distributed conductor; the other way is reducing the internal resistance while keeping the light transmission (device input/output) unchanged. The new conductor layout of the present invention can improve the current and heat uniformity over the TC film, and prevent the TC film from suffering other damages, thereby achieving better reliability. Furthermore, the conductor layout can improve uniformity of large area device by equalizing the sheet resistance across transmission surface.

Other aspects, features, and advantages of this invention will become apparent from the following detailed description when taken in conjunction with the accompanying drawings, which are a part of this disclosure and which illustrate, by way of example, principles of this invention.

### BRIEF DESCRIPTION OF THE DRAWINGS

The accompanying drawings facilitate an understanding of the various embodiments of this invention. In such drawings:

FIG. 1 shows a conventional TC film with bus-bar structure used for OE device;

FIG. 2 is a schematic diagram illustrating the TC film shown in FIG. 1;

FIG. 3 shows the plot of heat density for the TC film shown in FIG. 1;

FIG. 4 shows a transparent conductive film used on the OE device shown in FIG. 1, according to the first embodiment of the present invention;

FIG. 5 is an enlarged view of one of the conductors of the TC film shown in FIG. 4;

FIG. 6 shows one of the conductors of the TC film according to the second embodiment of the present invention;

FIG. 7 shows one of the conductors of the TC film according to the third embodiment of the present invention;

FIG. 8 is a table to illustrate the different characteristics of the conductors with different shape or dimension;

FIG. 9 shows one of the conductors of the TC film according to the forth embodiment of the present invention;

FIG. 10 is a schematic diagram illustrating the TC film of the forth embodiment as a sample to be tested;

FIG. 11a shows the current distribution deduced from the surface potential of the sample by measuring;

FIG. 11b shows the current distribution deduced from the surface potential of the sample by simulating;

FIG. 12 is a top view of the transparent conductive (TC) film shown in FIG. 4;

FIG. 13a is a contour plot of a direct coupling pattern modeled;

FIG. 13b is a contour plot of an indirect coupling pattern modeled;

FIG. 14 is a schematic diagram of part of the TC film shown in FIG. 12 for illustrating the layout and dimension of the conductors;

FIG. 15 and FIG. 16 are two plots provided to illustrate the advantage of the conductor layout of the present invention;

FIG. 17 is a schematic diagram illustrating the TC film of the fifth embodiment of the present invention.

### DETAILED DESCRIPTION OF ILLUSTRATED EMBODIMENTS

Various preferred embodiments of the invention will now be described with reference to the figures, wherein like reference numerals designate similar parts throughout the various views. As indicated above, the invention is directed to a transparent conductive (TC) film including a main transparent conductive layer and a plurality of conductors electrically contacting with the main transparent conductive layer. The conductors are disposed on the surface of the main transparent conductive layer separately from each other for collecting electrical current which flow in the vicinity, thereby reducing the internal resistance and/or allowing thinner TC film to be used with no impairment in application performance.

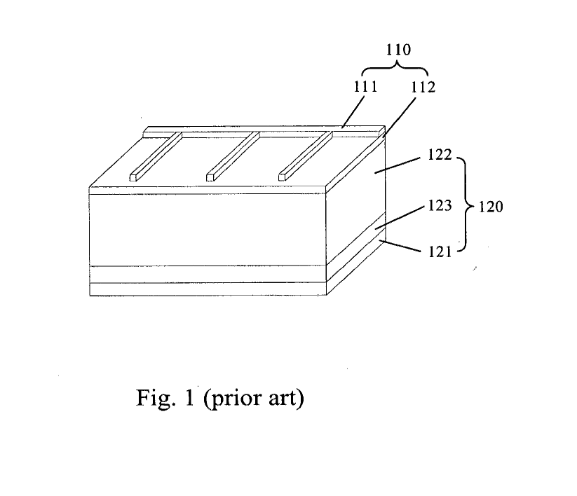

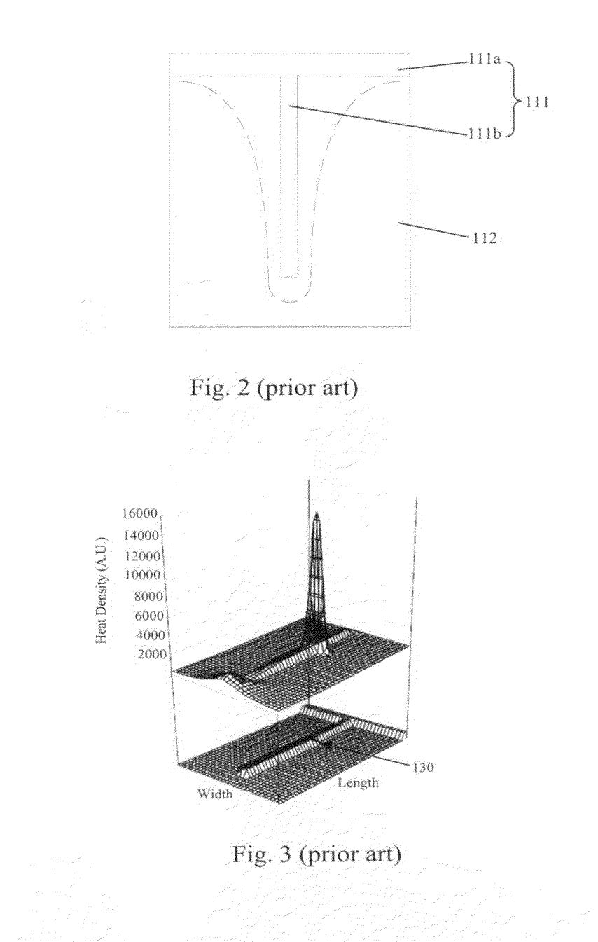

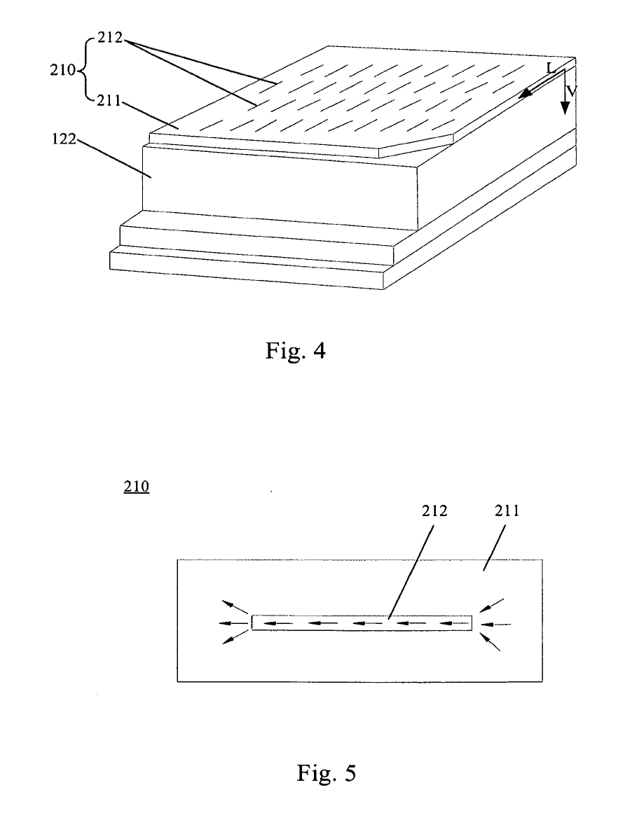

FIG. 4 shows a transparent conductive (TC) film 210 of the first embodiment of the present invention used on the OE device 120 shown in FIG. 1. Referring to FIG. 4, the transparent conductive film 210 includes a main transparent conductive layer 211 and many conductors 212 formed on the main transparent conductive layer 211. Concretely, the main transparent conductive layer 211 has a top surface on which the conductors 212 disposed and a bottom surface which contacts with the active layer 122 of the OE device 120 directly. In this embodiment, the main transparent conductive layer 211 is made of homogenous materials with good conductivity, such as metal oxides (including indium tin oxide (ITO), antinomy tin oxide (ATO), zinc oxide (ZnO) and their derivative), organic materials or nano-materials. In another embodiment, the main transparent conductive layer 211 can have a layer body which incorporates nano-particle, nano-wire or plasmonic structure or layers therein.

As shown in FIG. 4, the electrical current which flows in the OE device in each cell comprise of a vertical component (as the arrowhead V shown) and a lateral component (as the arrowhead L shown). The vertical component is the electrical current which is perpendicular to the surface of the TC film 210 and comes from or into the active layer 122. When the size of the cell is comparatively small to the entire TC film 210, the current injection or collection to the active layer 122 is uniform over the cell area. This uniform flow of vertical current is independent of the flow of lateral current and can be approximated with the slowly-varying envelope model when it is sufficiently small. While, the lateral component is the electrical current which is parallel to and flows in the TC film 210. Regardless of the size of the cell, the lateral component of current which flows in the vicinity of the conductor 212 on the TC film 210 is not uniform.

In this embodiment, the conductor 212 is a straight strip which extends along the direction of the lateral component of electrical current. Concretely, the conductor 212 is a thin film which is usually made of aluminum, nickel or silver-containing paste to obtain good conductivity. This thin film conductor 212 can be formed on the surface of the main transparent conductive layer 211 by stenciling, touch-transfer or all kinds of printing, such as ink jet printing, electrostatic printing, monographic printing or magnetographic printing and so on. Preferably, the conductor 212 also can be made of the same materials as that made of the main transparent conductive layer 211, thereby simplifying the manufacturing process of the present invention.

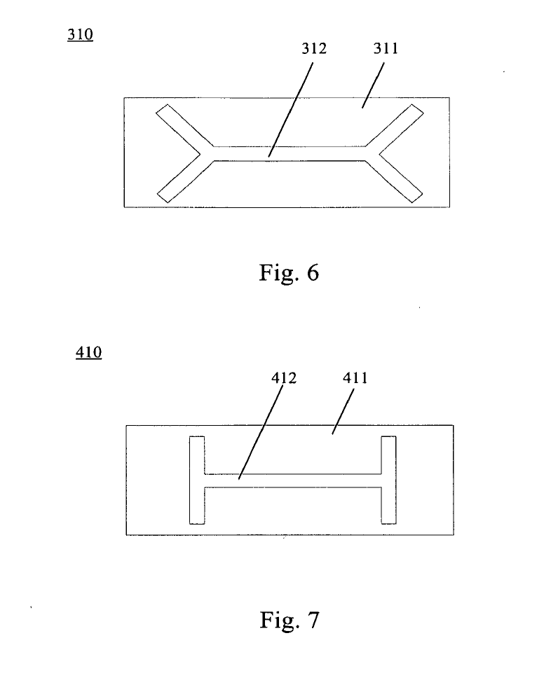

FIG. 5 is an enlarged view of one of the conductors shown in FIG. 4, wherein, the arrowheads are used to show the direction of electrical current flow in the TC film 210. As shown in FIG. 5, the conductors 212 formed on the main transparent conductive layer 211 are provided to collect electrical current. The lateral component of electrical current tends to flow in the conductor 212, because the conductor 212 is used to serve as a low resistive path (or even a short circuit path). By this token, this working mechanism is the reason why the resistance of TC film 210 can be reduced with the help of conductors 212.

FIG. 6 shows one of the conductors of the TC film according to the second embodiment of the present invention. Referring to FIG. 6, the TC film 310 of the second embodiment includes conductors 312 and a main transparent conductive layer 311. Preferably, the conductor 312 is a conductive thin film with Y-branch shape. FIG. 7 shows one of the conductors of the TC film according to the third embodiment of the present invention. As shown in FIG. 7, similarly, the TC film 410 of the third embodiment includes conductors 412 and a main transparent conductive layer 411. Preferably, the conductor 412 is a conductive thin film with H-shape.

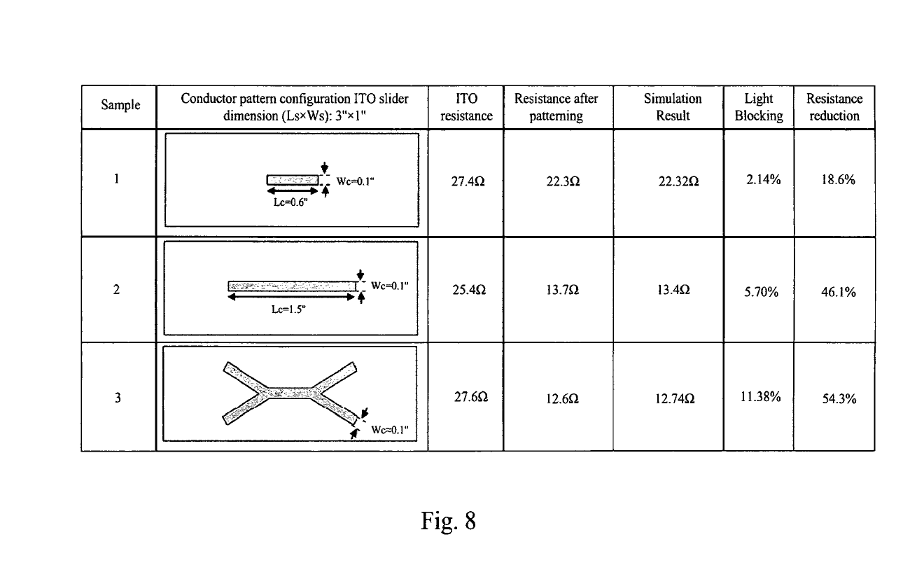

As shown in FIG. 8, there are three samples of the conductors with different shape or dimension formed on three indium-tin-oxide (ITO) glass slides (main transparent conductive layers) respectively. Each sample of conductors consists of 100 nm thick gold deposited by sputtering and 2 um thick electroplated copper so as provide a short circuit path for electrical current on the glass slides. Sample 1 is a short copper strip with a width of 0.1 inch ( 1/10 of ITO slide width) and a length of 0.6 inch ( 2/10 of ITO slide length). Sample 2 is a longer copper strip with a width of 0.1 inch ( 1/10 of ITO slide width) and a length of 1.5 inch ( 5/10 of ITO slide length). Sample 3 is a Y-branch conductor with a width of around 0.1 inch and a length longer than the sample 2. From this table, it is observed that the resistance reduction in cell has stronger dependent on the length in the direction of current rather than other factor.

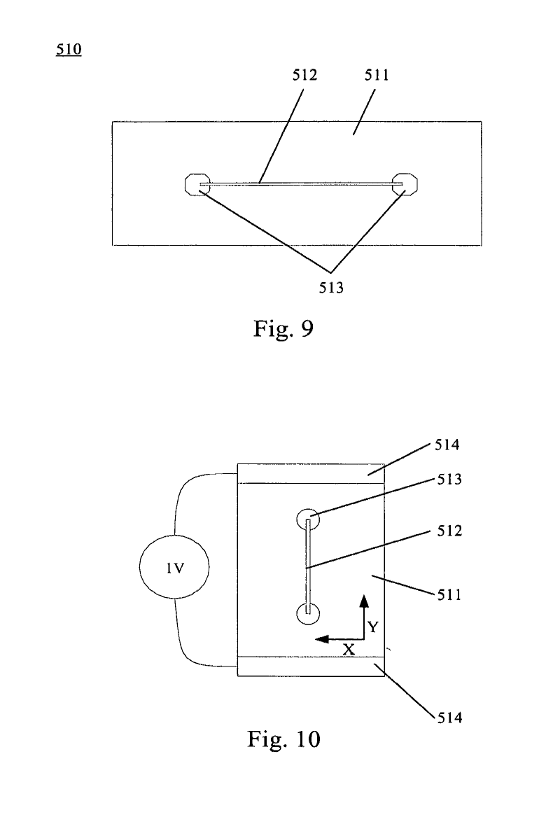

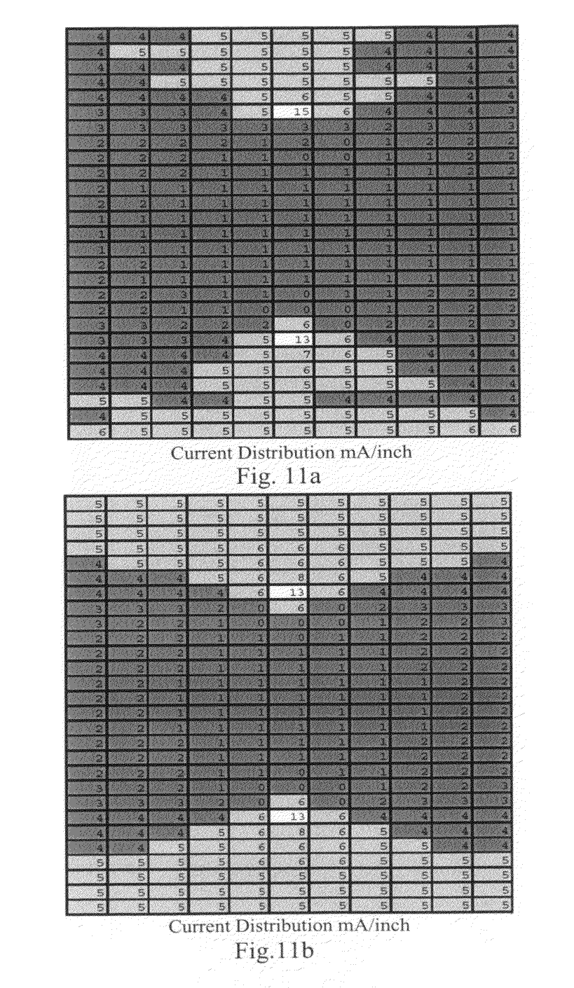

According to the forth embodiment of the present invention, as shown in FIG. 9, the conductor 512 formed on the main transparent conductive layer 511 is a wire. The wire 512 has at least two electric contacts to electrically contact with the main transparent conductive layer 511 to form the TC film 510 with the main transparent conductive layer 511. Concretely, the main transparent conductive layer 511 is formed by indium-tin-oxide (ITO) glass slide whose sheet resistance is 9 ohm/sq. This ITO glass slide 511 has two zero ohm chip resistors 513 with a size of 0.75×0.75×1.5 mm bonded thereon by silver-load epoxy. The two resistors 513 are disposed at a position 0.75 inch away from the edges of the glass slide 511 and interconnected by the wire 512 (length of 1.5 inch) using the same silver-load epoxy. Now, take this embodiment as a sample to measure the resistance of the TC film. Referring to FIG. 10, two press-contact electrodes 514 across two ends on TC film 510 are used to apply a voltage whose value is 1V. A micro-probe (not shown) connected to a voltmeter can be used to measure the potential on the sample surface in resolution of 0.1 inch in both X and Y direction. Upon the surface potential is recorded, current distribution and the equivalence resistance of the cell can be deduced. FIG. 11a is the current distribution deduced from the surface potential of the sample by measuring. FIG. 11b is the current distribution deduced from the surface potential of the sample by simulating. The measured and modeled resistances of this sample are 14 Ohm and 14.2 Ohm respectively. While, before the additional structure (conductor 512) added on the ITO glass slide, the resistance measured across to press-contact electrodes 514 is 28 Ohm. The reduction of sheet resistance is found to be around 50% where as the percentage of shading (conductor surface) is below 1% of the entire surface of the TC film.

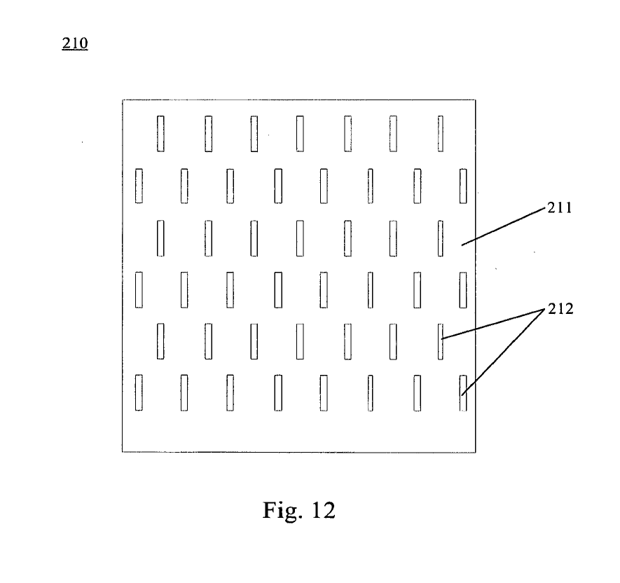

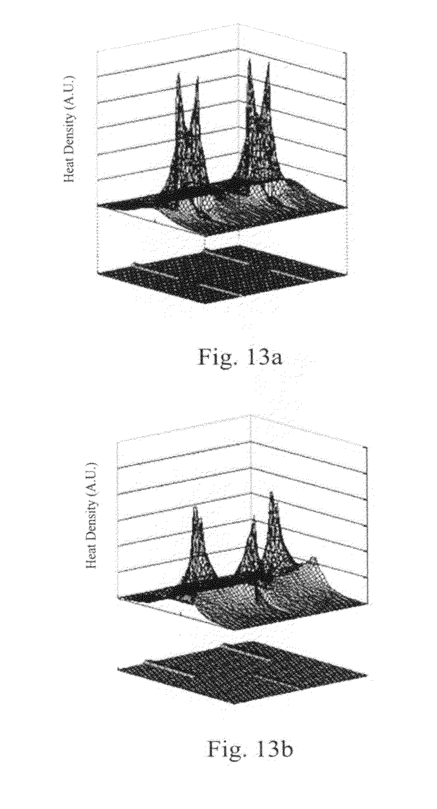

FIG. 12 is a top view of the transparent conductive (TC) film 210 according to the first embodiment of the present invention. As shown in FIG. 12, the conductors 212 are arranged in rows. Preferably, the conductors 212 located on two adjacent rows are staggered with each other, that is, the conductors 212 on each row are offset with respect to the conductors 212 on previous row, thereby forming an indirect current coupling between conductors 212 from row to row. This indirect coupling pattern can effectively reduce the heat generation when current pass through the TC film 210. However, if the offset between the conductors 212 located on two adjacent rows is zero, the conductors 212 on two adjacent rows are facing to each other directly from head to tail thereby forming a direct coupling pattern. FIG. 13a and FIG. 13b are the contour plots of a direct coupling pattern modeled and an indirect coupling pattern modeled. As shown in FIG. 13a and FIG. 13b, the heat density of the indirect coupling pattern obtained by modeling is lower compared to that of the direct coupling pattern.

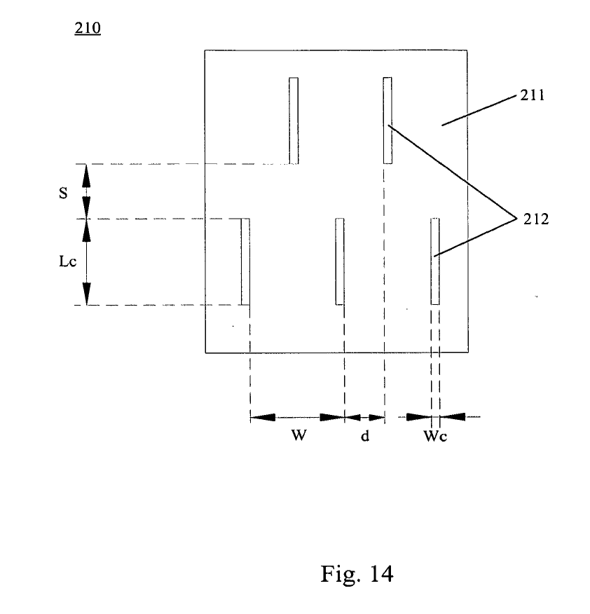

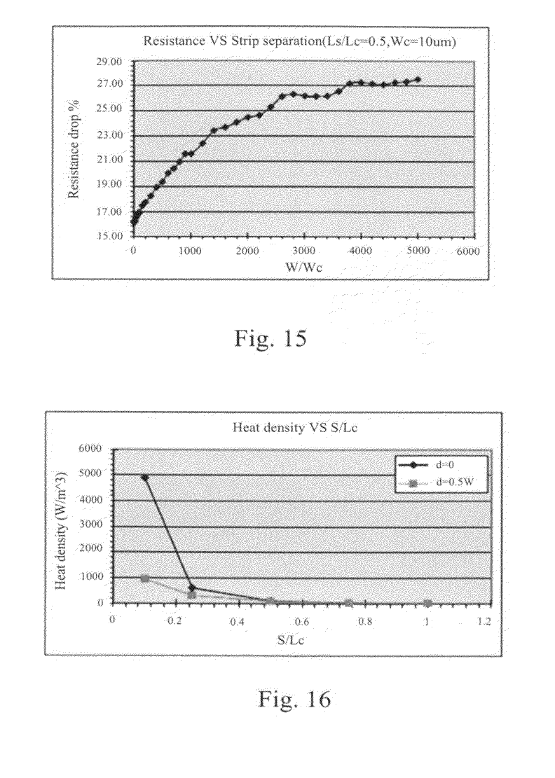

FIGS. 14-16 are provided to illustrate the advantage of the conductor layout of the present invention. As shown in FIG. 14, in the width direction of the conductor 212, the distance between two adjacent conductors 212 is defined to be “W”; in the length direction of the conductor 212, the distance between two adjacent conductors 212 is defined to be “S”; the offset between the conductors 212 located on two adjacent rows is defined to be “d”. FIG. 15 shows the resistance drop varying with the change of the parameter W/Wc (wherein We denotes the width of the conductor). From this plot, is can be deduced that the increase of the distance W will increase the resistance drop of the TC film. FIG. 16 shows two situations where the value of offset d equal to zero and 0.5 W. As shown in FIG. 16, the heat densities increase drastically as the value of S/Lc (wherein Lc denotes the length of the conductor) is smaller than 0.2 for the case that the value of offset d equal to zero. While, for the case that the value of offset d equal to 0.5 W, the heat density is about five time smaller than that of d=0, when the value of S/Lc equal to 0.1. The modeling result confirms the conductor layout of the present invention is effective in reducing joule-heating cause by conductors.

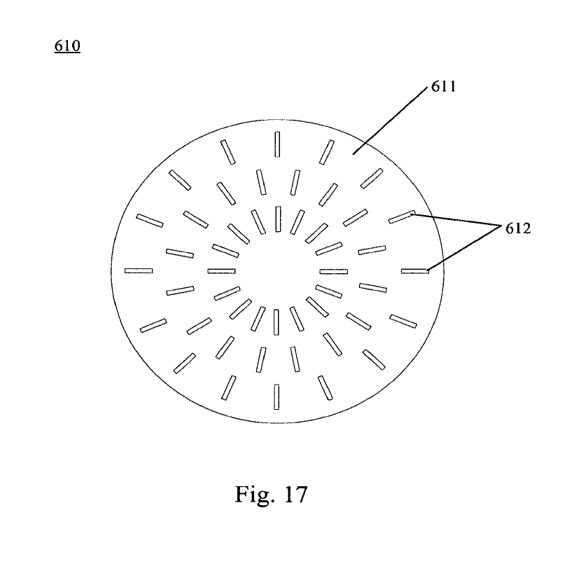

FIG. 17 shows a TC film according to the fifth embodiment of the present invention. As shown in FIG. 17, the TC film 610 includes a main transparent conductive layer 611 and a plurality of conductors 612 form on the surface of the main transparent conductive layer 611. In this embodiment, the main transparent conductive layer 611 is a round film, and each conductor 612 is a straight strip which extends along the direction of the lateral component of electrical current. As the electrical current distribution in this TC film 610 is radial, the conductors 612 are arranged to be a round shape formed by a series of concentric circles and, preferably, the conductors 612 located on two adjacent concentric circles are staggered with each other.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. A transparent conductive film for optoelectronic device, comprising:
a main transparent conductive layer;
a plurality of conductors electrically contacting with the main transparent conductive layer;
wherein the conductors are disposed on the surface of the main transparent conductive layer separately from each other.

2. The transparent conductive film as claimed in claim 1, wherein the conductors extend along the direction of the electrical current which flows in the transparent conductive film.

3. The transparent conductive film as claimed in claim 2, wherein the conductors are arranged in rows.

4. The transparent conductive film as claimed in claim 3, wherein the conductors located on two adjacent rows are staggered with each other.

5. The transparent conductive film as claimed in claim 2, wherein the conductors are arranged to be a round shape formed by a series of concentric circles.

6. The transparent conductive film as claimed in claim 5, wherein the conductors located on two adjacent concentric circles are staggered with each other.

7. The transparent conductive film as claimed in claim 1, wherein the conductor is a conducting thin film whose surface contacts with the main transparent conductive layer fully.

8. The transparent conductive film as claimed in claim 7, wherein the shape of the conductor is straight strip, Y-branch shape or H-shape.

9. The transparent conductive film as claimed in claim 1, the conductor is a wire which has at least two electric contacts to electrically contact with the main transparent conductive layer.

10. The transparent conductive film as claimed in claim 1, wherein the conductor is made of the same material as that of the main transparent conductive layer.

11. The transparent conductive film as claimed in claim 1, wherein the main transparent conductive layer has a layer body which incorporates nano-particle, nano-wire or plasmonic structure or layers therein.

12. The transparent conductive film as claimed in claim 1, wherein the main transparent conductive layer contacts with an active layer of the optoelectronic device directly.
